(19) United States
(12) Patent Application Publication
(10) Pub. No.: US 2025/0096012 A1
(43) Pub. Date: Mar. 20, 2025

(54) SUBSTRATE PROCESSING MODULE AND SUBSTRATE PROCESSING METHOD

(71) Applicant: EBARA CORPORATION, Tokyo (JP)

(72) Inventor: Tomoatsu ISHIBASHI, Tokyo (JP)

(21) Appl. No.: 18/884,378

(22) Filed: Sep. 13, 2024

(30) Foreign Application Priority Data
Sep. 19, 2023 (JP) 2023-150967

(51) Int. Cl. H01L 21/67; B08B 3/00; B08B 3/12; H01L 21/02

(52) U.S. Cl. CPC H01L 21/67046; B08B 3/003; B08B 3/12; H01L 21/02096

(57) ABSTRACT

A substrate processing module capable of improving a cleaning efficiency of an object to be cleaned is disclosed. The substrate processing module includes a gas supply device configured to supply a gas to a gap between a cleaning member and a surface to be cleaned. The gas supply device is configured to generate a fine bubble through the cleaning member.

### CROSS REFERENCE TO RELATED APPLICATION

This document claims priority to Japanese Patent Application No. 2023-150967 filed Sep. 19, 2023, the entire contents of which are hereby incorporated by reference.

### BACKGROUND

In recent years, with a miniaturization of semiconductor devices, various material films with different physical properties are formed on a substrate and then processed. In particular, in a damascene wiring formation process in which wiring grooves formed in the substrate are filled with metal, after the damascene wiring is formed, excess metal is removed by polishing using a polishing apparatus (CMP apparatus).

By removing excess metal, films with different wettability to water, such as metal films, barrier films, and insulating films, are present on the surface of the substrate. Residues of the polishing liquid (slurry) used in CMP polishing and polishing debris adhere to a surface of such films. If the surface of the film has a complex shape that is difficult to clean, if it is not cleaned sufficiently, the adhesion may cause leaks or cause poor adhesion, which may cause reliability problems.

In recent years, a size of particles, which are objects to be removed from the surface of the film, has become very small. Assuming that the size of the particle is about 20 nanometers, the size of a cleaning member in a conventional physical cleaning is very large compared to the particle. Therefore, there is a problem that the cleaning member cannot effectively remove the particle, and a cleaning efficiency of the object to be cleaned, such as the substrate, becomes very low.

### SUMMARY

Therefore, there are provided a substrate processing module and a substrate processing method that can improve the cleaning efficiency of the object to be cleaned.

Embodiments, which will be described below, relate to a substrate processing module and a substrate processing method.

In an embodiment, there is provided a substrate processing module for processing a substrate, comprising: a cleaning member having an open-cell foam structure; a gas supply device configured to supply a gas to a gap between the cleaning member and a surface to be cleaned of an object to be cleaned; and a liquid supply device configured to supply a liquid to the gap between the cleaning member and the surface to be cleaned, the gas supply device is configured to generate a fine bubble through the open-cell foam structure while supplying the liquid from the liquid supply device.

In an embodiment, the substrate processing module comprises a distance adjustment mechanism configured to approach or separate the cleaning member from the surface to be cleaned, and the distance adjustment mechanism is configured to move the cleaning member to a bubble contact position where the fine bubble comes into contact with the surface to be cleaned in a state where the fine bubble is held in the open-cell foam structure by the gas supply device.

In an embodiment, the distance adjustment mechanism is configured to move the cleaning member to a bubble separation position where the fine bubble is separated from the surface to be cleaned further than the bubble contact position, while continuously supplying the fine bubble from the open-cell foam structure by the gas supply device.

In an embodiment, the substrate processing module includes an ultrasonic vibrator configured to apply ultrasonic waves to the liquid supplied from the liquid supply device.

In an embodiment, the substrate processing module comprises a temperature regulator configured to regulate a temperature of the liquid supplied from the liquid supply device.

In an embodiment, the open-cell foam structure is made of a grounded conductive resin.

In an embodiment, the open-cell foam structure of the conductive resin has fine pores.

In an embodiment, the substrate processing module comprises a moving mechanism configured to move the cleaning member parallel to the surface to be cleaned, and the moving mechanism is configured to move the cleaning member in a radial direction of the surface to be cleaned while the fine bubble is in contact with the surface to be cleaned.

In an embodiment, there is provided a substrate processing method for processing a substrate, comprising: supplying a liquid to a gap between a cleaning member having an open-cell foam structure and a surface to be cleaned of an object to be cleaned; and supplying a fine bubble to the gap between the cleaning member and the surface to be cleaned through the open-cell foam structure while supplying the liquid.

In an embodiment, comprising: moving the cleaning member to a bubble contact position where the fine bubble comes into contact with the surface to be cleaned in a state where the fine bubble is held in the open-cell foam structure.

In an embodiment, comprising: moving the cleaning member to a bubble separation position where the fine bubble is separated from the surface to be cleaned further than the bubble contact position while continuously supplying the fine bubble from the open-cell foam structure.

In an embodiment, comprising: applying ultrasonic waves to the liquid when the fine bubble is supplied to the gap between the cleaning member and the surface to be cleaned.

In an embodiment, comprising: regulating a temperature of the liquid when the fine bubble is supplied to the gap between the cleaning member and the surface to be cleaned.

In an embodiment, the open-cell foam structure is made of a grounded conductive resin.

In an embodiment, the open-cell foam structure of the conductive resin has fine pores.

In an embodiment, comprising: comprising: moving the cleaning member in a radial direction of the surface to be cleaned while the fine bubble is in contact with the surface to be cleaned.

The substrate processing module is configured to generate fine bubbles through the open-cell foam structure, thereby improving the cleaning efficiency of the object to be cleaned.

### BRIEF DESCRIPTION OF THE DRAWINGS

FIG. 1 is a view showing a substrate processing apparatus;

FIG. 2 is a view showing a polishing module;

FIG. 3 is a view showing a substrate cleaning module;

FIG. 4A is a view showing a cleaning member having a cylindrical shape;

FIG. 4B is a view showing the cleaning member having a rectangular prism shape;

FIG. 5 is a view showing the substrate cleaning module;

FIG. 6 is a view showing the substrate cleaning module;

FIG. 7 is a schematic view of a substrate processing module including a fine bubble cleaning mechanism;

FIG. 8 is a view showing another embodiment of the fine bubble cleaning mechanism;

FIG. 9A is a view showing how fine bubbles are generated from the cleaning member;

FIG. 9B is a view showing how the cleaning member removes particles;

FIG. 9C is a view showing how fine bubbles are generated from the cleaning member;

FIG. 10A is a views showing the cleaning member moved to a bubble separation position;

FIG. 10B is a view showing the cleaning member moved to the bubble separation position;

FIG. 11 is a view showing the substrate cleaning module that holds a wafer vertically;

FIG. 12 is a view showing the substrate cleaning module that holds the wafer vertically; and

FIG. 13 is a view showing the substrate cleaning module that holds the wafer vertically.

### DESCRIPTION OF EMBODIMENTS

Hereinafter, embodiments will be described with reference to the drawings. In the drawings described below, the same or corresponding components are denoted by the same reference numerals, and duplicated descriptions will be omitted. In the embodiments described below, a configuration of one embodiment that is not particularly described is the same as the other embodiments, so duplicated descriptions will be omitted.

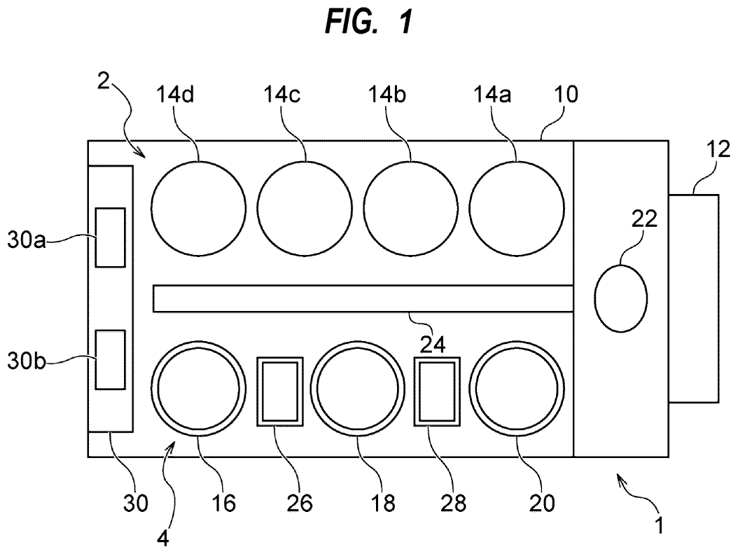

FIG. 1 is a view showing a substrate processing apparatus. As shown in FIG. 1, the substrate processing apparatus 1 includes a housing 10 and a load port 12 on which a substrate cassette for stocking a large number of wafers is placed. The load port 12 is arranged adjacent to the housing 10. The wafer is, for example, a semiconductor wafer, and is an example of a substrate.

The substrate processing apparatus 1 includes a polishing unit 2 and a cleaning unit 4 arranged inside the housing 10. The polishing unit 2 includes a plurality of (four in this embodiment) polishing modules 14a to 14d. The cleaning unit 4 includes a first cleaning module 16 and a second cleaning module 18 that clean the polished substrate, and a drying module 20 that dries the cleaned substrate.

The polishing modules 14a to 14d are arranged along a longitudinal direction of the substrate processing apparatus 1. Similarly, the first cleaning module 16, the second cleaning module 18, and the drying module 20 are arranged along the longitudinal direction of the substrate processing apparatus 1.

In this specification, the polishing modules 14a to 14d, the first cleaning module 16, the second cleaning module 18, and the drying module 20 are collectively referred to as substrate processing modules for processing the substrate. In particular, the first cleaning module 16 and the second cleaning module 18 are collectively referred to as a substrate cleaning module for cleaning the substrate.

The substrate processing apparatus 1 includes a first transport robot 22 arranged adjacent to the load port 12, and a transport module 24 arranged adjacent to the polishing modules 14a to 14d. The first transport robot 22 receives the substrate before polishing from the load port 12 and delivers the substrate to the transport module 24, and receives the dried substrate from the drying module 20 and returns the substrate to the load port 12. The transport module 24 transports the substrate received from the first transport robot 22, and delivers the substrate between the polishing modules 14a to 14d.

The substrate processing apparatus 1 includes a second transport robot 26 arranged between the first cleaning module 16 and the second cleaning module 18, and a third transport robot 28 arranged between the second cleaning module 18 and the drying module 20. The second transport robot 26 delivers the substrate between the transport module 24 and each of the cleaning modules 16 and 18. The third transport robot 28 delivers the substrate between each of the modules 18 and 20.

The substrate processing apparatus 1 includes a control device 30 arranged inside the housing 10. The control device 30 is configured to control an operation of each device of the substrate processing apparatus 1 (e.g., the polishing modules 14a to 14d, the cleaning modules 16 and 18, the drying module 20, etc.).

More specifically, the control device 30 is configured from a dedicated computer or a general-purpose computer. The control device 30 includes a storage unit 30a in which programs and data are stored, and a calculation unit 30b such as a CPU (Central Processing Unit) or a GPU (Graphics Processing Unit) that performs calculations according to the programs stored in the storage unit 30a.

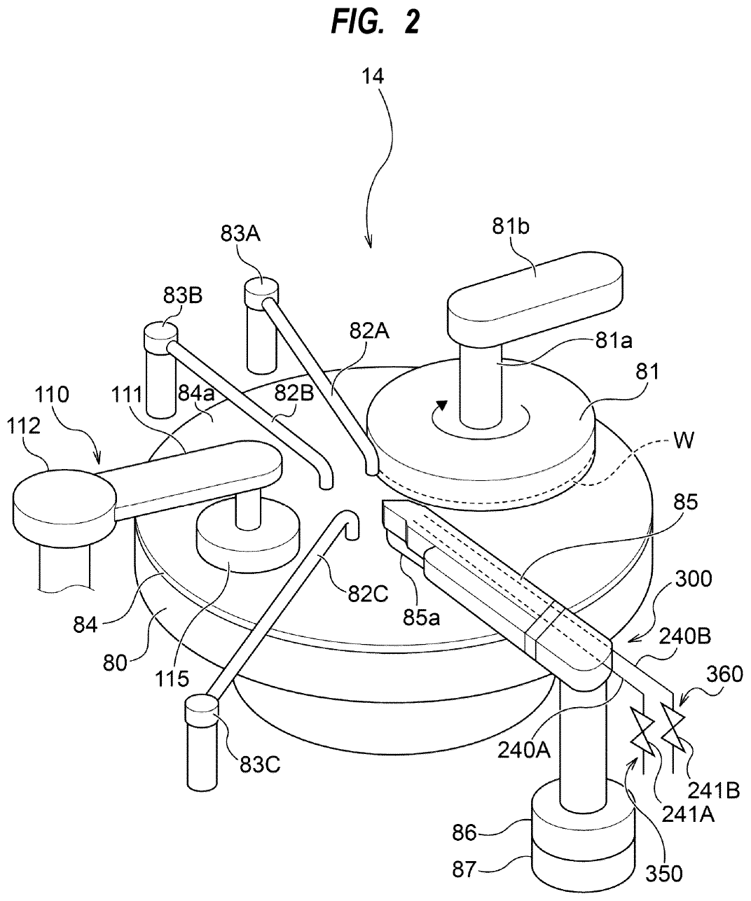

FIG. 2 is a view showing the polishing module. In the embodiment described below, the polishing modules 14a to 14d may be collectively referred to as the polishing module 14. The polishing module 14 includes a polishing table 80 that supports a polishing pad 84 having a polishing surface 84a, a substrate holding mechanism (top ring) 81 that holds a wafer W and presses it against the polishing surface 84a, and a supply nozzle (slurry supply nozzle in this embodiment) 82A that supplies a slurry (polishing liquid) to the polishing surface 84a.

The polishing module 14 includes a supply nozzle (in this embodiment, a pure water supply nozzle) 82B that supplies pure water onto the polishing surface 84a, a supply nozzle (in this embodiment, a chemical supply nozzle) 82C that supplies a chemical liquid onto the polishing surface 84a, and an atomizer 85 that supplies a cleaning fluid to remove the slurry adhering to the polishing surface 84a.

The polishing module 14 includes an oscillation mechanism 86 that oscillates the atomizer 85 in a horizontal direction, and a lifting mechanism 87 that raises and lowers the atomizer 85. The oscillation mechanism 86 is a moving mechanism that moves the atomizer 85 parallel to the polishing surface 84a of the polishing pad 84. The lifting mechanism 87 is configured to approach or separate the atomizer 85 from the polishing pad 84. Therefore, the lifting mechanism 87 may be called a distance adjustment mechanism.

In the embodiment shown in FIG. 2, the polishing module 14 includes a plurality of supply nozzles 82A, 82B, and 82C, but in one embodiment, the polishing module 14 may include a single supply nozzle that selectively supplies any one of the liquids, slurry, pure water, and chemical liquid, instead of the supply nozzles 82A, 82B, and 82C.

The polishing module 14 includes a dressing device 110 for dressing the polishing pad 84. The dressing device 110 includes a dresser 115 that is in sliding contact with the polishing surface 84a of the polishing pad 84, a dresser arm 111 that supports the dresser 115, and a dresser pivot shaft 112 that pivots the dresser arm 111. The dresser pivot shaft 112 is arranged outside the polishing pad 84.

The dresser 115 oscillates on the polishing surface 84a as the dresser arm 111 pivots. A lower surface of the dresser 115 constitutes a dressing surface made of a large number of abrasive grains such as diamond particles. The dresser 115 rotates while oscillating on the polishing surface 84a, and dresses the polishing surface by slightly scraping off the polishing pad 84.

The polishing table 80 is formed in a disk shape and is configured to be rotatable about its central axis as an axis of rotation. The polishing pad 84 is attached to an upper surface of the polishing table 80. When the polishing table 80 is rotated by a motor (not shown), the polishing pad 84 rotates integrally with the polishing table 80.

The top ring 81 holds the wafer W on its lower surface by vacuum suction or the like. The top ring 81 is configured to be rotatable together with the wafer W by a power from a motor (not shown). An upper portion of the top ring 81 is connected to a support arm 81b via a shaft 81a.

The top ring 81 can be moved up and down by a lifting mechanism (e.g., an air cylinder) (not shown). The lifting mechanism is configured to adjust a distance between the top ring 81 and the polishing table 80. With this configuration, the top ring 81 presses the wafer W held therein against the polishing surface 84a of the polishing pad 84.

The support arm 81b is configured to be able to oscillate by a moving mechanism (e.g., a motor) not shown. The moving mechanism is configured to move the top ring 81 in a direction parallel to the polishing surface 84a. In this embodiment, the top ring 81 is configured to be movable between a receiving position for the wafer W not shown and a position above the polishing pad 84, and a pressing position of the wafer W against the polishing pad 84 can be changed.

The slurry supply nozzle 82A is provided above the polishing table 80, and supplies the slurry onto the polishing pad 84. The slurry supply nozzle 82A is supported by a shaft 83A. The shaft 83A is configured to be movable by a motor (not shown). Therefore, the slurry supply nozzle 82A can change a position at which the slurry is dropped around the shaft 83A during a polishing process of the wafer W. In this manner, the slurry supply nozzle 82A supplies the slurry so that it penetrates into a contact interface between the rotating wafer W and the polishing pad 84.

The pure water supply nozzle 82B is provided above the polishing table 80 and supplies pure water onto the polishing pad 84. The pure water supply nozzle 82B is supported by a shaft 83B. Similarly, the chemical liquid supply nozzle 82C is provided above the polishing table 80 and supplies the chemical liquid onto the polishing pad 84. The chemical liquid supply nozzle 82C is supported by a shaft 83C. These shafts 83B and 83C are configured to be movable by a motor (not shown).

The atomizer 85 is provided above the polishing table 80 and extends along a radial direction of the polishing table 80. Immediately after the polishing process of the wafer W with the slurry, the atomizer 85 injects a cleaning fluid at a predetermined flow rate toward the polishing pad 84 to wash away a part of the slurry adhering to the polishing surface 84a and the wafer W. The cleaning fluid is composed of a mixed fluid of a liquid (usually pure water) and a gas (e.g., an inert gas such as nitrogen gas).

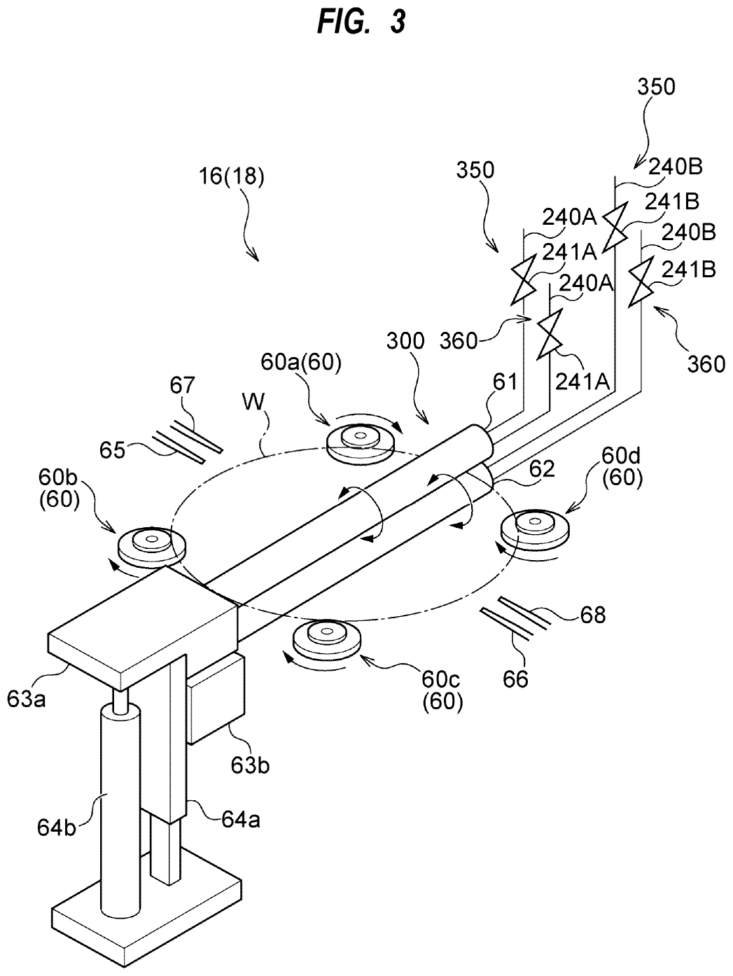

FIG. 3 is a view showing the substrate cleaning module. As shown in FIG. 3, the substrate cleaning module (i.e., the first cleaning module 16 and/or the second cleaning module 18) includes a substrate holding mechanism 60 for holding and rotating the wafer W, cleaning members 61 and 62 for cleaning the wafer W, supply nozzles (chemical liquid supply nozzles in this embodiment) 65 and 66 for supplying a processing liquid (diluted chemical liquid in this embodiment) toward front and back surfaces of the wafer W, and supply nozzles (pure water supply nozzles in this embodiment) 67 and 68 for supplying a processing liquid (pure water in this embodiment) toward the front and back surfaces of the wafer W.

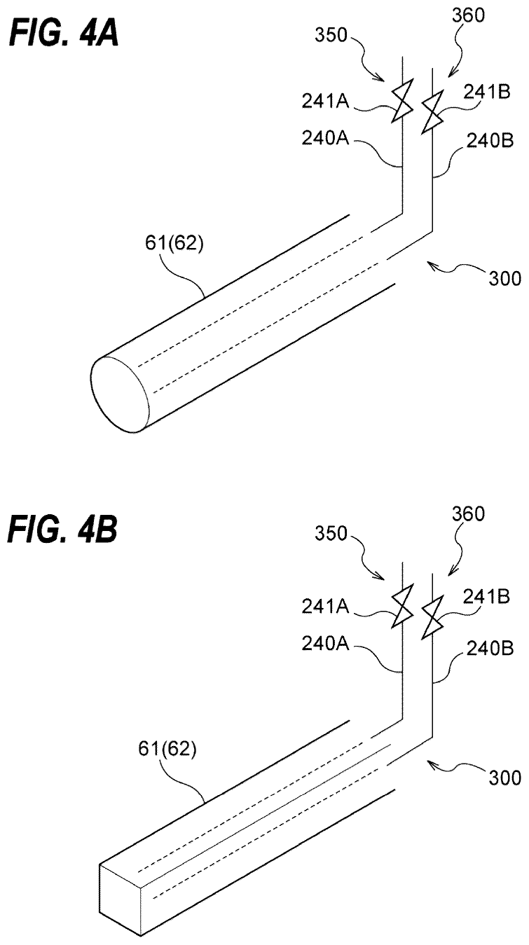

FIG. 4A is a view showing a cleaning member having a cylindrical shape, and FIG. 4B is a view showing a cleaning member having a rectangular prism shape. In the embodiment shown in FIG. 4A, each of the cleaning members 61 and 62 has a cylindrical shape and the longitudinal length longer than a diameter of the wafer W.

In an embodiment shown in FIG. 4B, each of the cleaning members 61, 62 has a rectangular prism shape, and a length of the longitudinal direction is longer than the diameter of the wafer W. In this manner, each of the cleaning members 61, 62 does not need to have a specific shape, and may have a cylindrical shape or a rectangular prism shape. In one embodiment, one of the cleaning members 61, 62 may have a cylindrical shape and the other may have a rectangular prism shape.

As shown in FIG. 3, the cleaning members 61, 62 are arranged such that a direction of their central axes is parallel to the surfaces (i.e., the front and back surfaces) of the wafer W. Hereinafter, the cleaning member 61 may be referred to as an upper roll cleaning member 61, and the cleaning member 62 may be referred to as a lower roll cleaning member 62.

The substrate holding mechanism 60 includes four rollers 60a to 60d that horizontally hold and rotate the wafer W with the surface of the wafer W facing upward. The rollers 60a to 60d are configured to be movable in a direction to approach or separate from each other by a drive mechanism (e.g., an air cylinder) not shown.

In this embodiment, the substrate holding mechanism 60 includes rollers 60a to 60d as its components, but the substrate holding mechanism 60 is not limited to rollers as long as it can hold a side surface of the wafer W. Instead of the rollers, the substrate holding mechanism 60 may include, for example, a plurality of clamps (not shown). The clamps are configured to be movable between a position for holding a peripheral portion of the wafer W and a position spaced apart from the wafer W.

The upper roll cleaning member 61 and the lower roll cleaning member 62 are supported by lifting mechanisms 64a and 64b, respectively, and can be moved up and down by the lifting mechanisms 64a and 64b. Examples of the lifting mechanisms 64a and 64b include a motor drive mechanism using a ball screw or an air cylinder.

When the wafer W is loaded or unloaded, the upper roll cleaning member 61 and the lower roll cleaning member 62 are spaced apart from each other. When cleaning the wafer W, the upper roll cleaning member 61 and the lower roll cleaning member 62 move in a direction to approach each other to be adjacent to the front and back surfaces of the wafer W. Thereafter, the upper roll cleaning member 61 and the lower roll cleaning member 62 are rotated by rotation mechanisms 63a and 63b, respectively, to clean the wafer W.

In this manner, each of the lifting mechanisms 64a, 64b is configured to approach or separate each of the cleaning members 61, 62 from the wafer W. Therefore, each of the lifting mechanisms 64a, 64b may be called a distance adjustment mechanism that adjusts the distance between the wafer W and the cleaning members 61, 62.

In the embodiment shown in FIG. 3, the substrate cleaning module supplies the liquid (more specifically, chemical liquid, pure water) onto the front and back surfaces of the wafer W through the supply nozzles 65, 66, 67, and 68 while the upper roll cleaning member 61 and the lower roll cleaning member 62 are cleaning the wafer W.

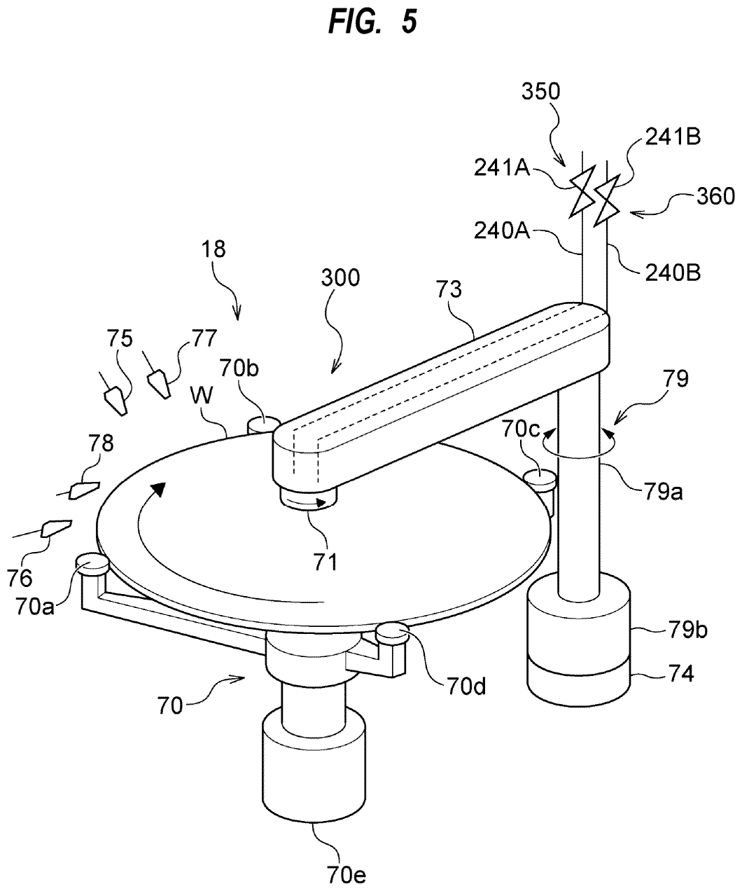

FIG. 5 is a view showing the substrate cleaning module. As shown in FIG. 5, the substrate cleaning module (i.e., the second cleaning module 18 and/or the first cleaning module 16) includes a substrate holding mechanism 70 for horizontally holding and rotating the wafer W, a cleaning member 71 for cleaning the wafer W, and an arm 73 coupled to the cleaning member 71.

The substrate cleaning module includes an arm oscillation mechanism 79 that oscillates the arm 73 horizontally, supply nozzles (in this embodiment, chemical liquid supply nozzles) 75, 76 that supply a processing liquid (in this embodiment, diluted chemical liquid) toward the front and back surfaces of the wafer W, and supply nozzles (in this embodiment, pure water supply nozzles) 77, 78 that supply a processing liquid (in this embodiment, pure water) toward the front and back surfaces of the wafer W.

The substrate holding mechanism 70 includes chucks 70a to 70d for holding the peripheral portion of the wafer W, and a motor 70e coupled to the chucks 70a to 70d. The chucks 70a to 70d hold the wafer W, and the motor 70e is driven to rotate the wafer W about its axis.

The cleaning member 71 has a pencil shape, and is configured to clean the wafer W while rotating around the central axis of the cleaning member 71. Hereinafter, the cleaning member 71 may be referred to as a pencil cleaning member 71.

The arm 73 is arranged above the wafer W and is coupled to the arm oscillation mechanism 79. The arm oscillation mechanism 79 is a moving mechanism that moves the cleaning member 71 in parallel with the surface of the wafer W.

The arm oscillation mechanism 79 includes a pivot shaft 79a and a rotation mechanism 79b. One end of the arm 73 is coupled to the pivot shaft 79a, and the other end of the arm 73 is coupled to the pencil cleaning member 71. A direction of the central axis of the pencil cleaning member 71 is perpendicular to the front surface (or the back surface) of the wafer W.

The rotation mechanism 79b that pivots the arm 73 is coupled to the pivot shaft 79a. The rotation mechanism 79b is configured to rotate the pivot shaft 79a to pivot the arm 73 within a plane parallel to the wafer W. The pencil cleaning member 71 moves in the radial direction of the wafer W by pivoting the arm 73.

The substrate cleaning module includes a lifting mechanism 74 that raises and lowers the cleaning member 71 (more specifically, the pivot shaft 79a). The lifting mechanism 74 is configured to approach or separate the cleaning member 71 from the wafer W. Therefore, the lifting mechanism 74 may be called a distance adjustment mechanism.

The pivot shaft 79a can be moved up and down by the lifting mechanism 74 to clean the wafer W. An example of the lifting mechanism 74 is a motor drive mechanism using a ball screw or an air cylinder.

In the embodiment shown in FIG. 5, the substrate cleaning module supplies the liquid (more specifically, chemical liquid, pure water) onto the front and back surfaces of the wafer W through the supply nozzles 75, 76, 77, and 78 while the pencil cleaning member 71 is cleaning the wafer W.

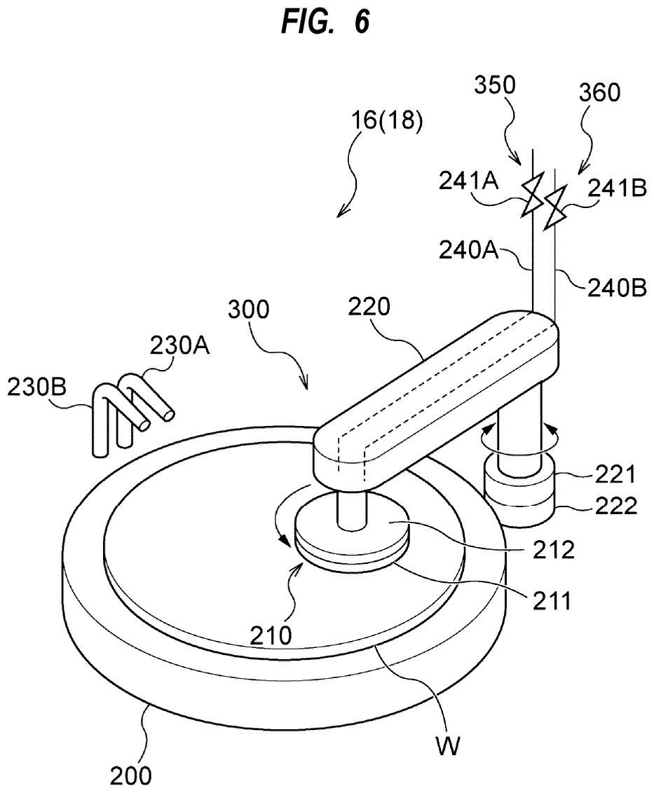

FIG. 6 is a view showing the substrate cleaning module. As shown in FIG. 6, the substrate cleaning module (i.e., the first cleaning module 16 and/or the second cleaning module 18) may include a cleaning structure 210 that cleans the wafer W and a rotary table 200 that horizontally supports the wafer W.

The cleaning structure 210 includes a cleaning member 211 that buffs the wafer W, and a buff head 212 that holds the cleaning member 211. A buff arm 220 that supports the cleaning structure 210 is configured to oscillate the cleaning structure 210 by an arm oscillation mechanism 221 that oscillates the buff arm 220 in the horizontal direction.

The arm oscillation mechanism 221 is a moving mechanism that moves the cleaning structure 210 parallel to the surface of the wafer W. The buff arm 220 is coupled to a lifting mechanism 222 that raises and lowers the cleaning structure 210 via the buff arm 220.

The lifting mechanism 222 is configured to approach or separate the cleaning structure 210 from the wafer W. Therefore, the lifting mechanism 222 may be called a distance adjustment mechanism. An example of the lifting mechanism 222 is a motor drive mechanism using a ball screw or an air cylinder.

In the embodiment shown in FIG. 6, the substrate cleaning module (i.e., the first cleaning module 16 and/or the second cleaning module 18) includes a supply nozzle (in this embodiment, a pure water supply nozzle) 230A for supplying pure water onto the surface of the wafer W, and a supply nozzle (in this embodiment, a chemical liquid supply nozzle) 230B for supplying the chemical liquid onto the surface of the wafer W.

The lifting mechanism 222 places the cleaning structure 210 at a predetermined position relative to the wafer W. In this state, when the buff arm 220 oscillates the buff head 212 while the rotary table 200 rotates the wafer W, the cleaning structure 210 (more specifically, the cleaning member 211) cleans the entire wafer W.

At this time, the cleaning structure 210 rotates by a rotation mechanism (e.g., a motor) not shown while cleaning the surface of the wafer W. Each of the supply nozzles 230A and 230B supplies the liquid (more specifically, chemical liquid or pure water) onto the surface of the wafer W while the cleaning structure 210 is cleaning the surface of the wafer W.

In general, the substrate cleaning module is configured to remove particles present on the surface of a wafer W, which is an object to be cleaned, by physical cleaning using the cleaning member. However, a size of the particles on the surface of the film formed on the surface of the wafer W is very small, while a size of the cleaning member is very large compared to the particles. Therefore, physical cleaning using the cleaning member cannot effectively remove the particles, and as a result, there is a risk that the cleaning efficiency of the object to be cleaned (more specifically, the wafer W) will be reduced.

It is also desirable to improve the cleaning efficiency of the object to be cleaned in the polishing module 14. More specifically, the atomizer 85 is configured to wash away the slurry adhering to the polishing surface 84a of the polishing pad 84, and it is desirable to effectively remove the slurry and improve the cleaning efficiency of the object to be cleaned (more specifically, the polishing pad 84) by the atomizer 85.

Therefore, the substrate processing module including the polishing module 14 and the cleaning modules 16 and 18 includes a fine bubble cleaning mechanism that can improve the cleaning efficiency of the object to be cleaned (e.g., the wafer W, the polishing pad 84). Configurations of the fine bubble cleaning mechanism will be described below with reference to the drawings.

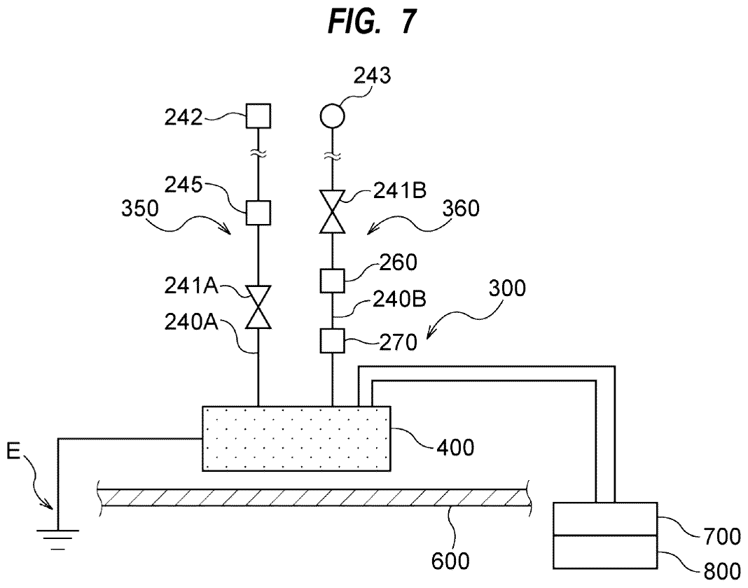

FIG. 7 is a schematic view of the substrate processing module including the fine bubble cleaning mechanism. In the embodiment shown in FIG. 7, an embodiment of the substrate processing module including a fine bubble cleaning mechanism 300 is described. In the embodiment, the fine bubble cleaning mechanism 300 is also applicable to the substrate processing module described with reference to FIGS. 2 to 6.

As shown in FIG. 7, the fine bubble cleaning mechanism 300 includes a cleaning member 400 having an open-cell foam structure, a gas supply device 350 that supplies the gas through the cleaning member 400 to a gap between the cleaning member 400 and a surface to be cleaned 600, and a liquid supply device 360 that supplies the liquid to the gap between the cleaning member 400 and the surface to be cleaned 600.

In an embodiment shown in FIG. 7, the cleaning member 400 has the open-cell foam structure. The open-cell foam structure is made of a material (e.g., a resin material) having fine pores, and is configured to allow fluids such as liquids and gases to pass through.

Unlike a closed-cell foam structure, the open-cell foam structure has a structure in which a large number of holes formed inside the open-cell foam structure are interconnected. An example of the resin material includes fluorine-containing resins (PTFE, PFA, PVDF, etc.), PPS, PP, PEEK, and polyimide.

The cleaning member 400 is a porous cleaning member having a surface parallel to the surface to be cleaned 600 while forming a narrow gap between the cleaning member 400 and the surface to be cleaned 600. The cleaning member 400 corresponds to at least one of the cleaning member 85a of the atomizer 85 (see FIG. 2), the cleaning members 61 and 62 (see FIG. 3), the cleaning member 71 (see FIG. 5), and the cleaning member 211 (see FIG. 6). The surface to be cleaned 600 corresponds to at least one of the front surface of the wafer W and the polishing surface 84a of the polishing pad 84.

The gas supply device 350 includes a gas supply line 240A extending to the cleaning member 400, and an on-off valve 241A connected to the gas supply line 240A. The gas supply line 240A is coupled to a gas supply source 242. The gas supply source 242 is configured to supply the gas (e.g., nitrogen gas, oxygen, an inert gas other than nitrogen gas, etc.) to the cleaning member 400 through the gas supply line 240A.

The liquid supply device 360 includes a liquid supply line 240B extending to the cleaning member 400, and an on-off valve 241B connected to the liquid supply line 240B. The liquid supply line 240B is coupled to a liquid supply source 243. The liquid supply source 243 is configured to supply a liquid (e.g., chemical liquid, pure water) to the cleaning member 400 through the liquid supply line 240B.

Each of the gas supply source 242 and the liquid supply source 243 may be a component of the substrate processing module, may be a component of the substrate processing apparatus 1, or may be arranged outside the substrate processing apparatus 1. For example, at least one of the gas supply source 242 and the liquid supply source 243 may be arranged at a location different from the substrate processing module. In this case, at least one of the gas and the liquid supplied from a location different from the substrate processing module is supplied onto the surface to be cleaned 600 through the cleaning member 400.

The on-off valves 241A and 241B are configured to open and close the gas supply line 240A and the liquid supply line 240B, respectively, and are electrically connected to the control device 30. The control device 30 is configured to control an opening and closing operations of the on-off valves 241A and 241B.

When the on-off valve 241A is opened, the gas from the gas supply source 242 is supplied through the gas supply line 240A to the cleaning member 400. The gas supplied to the cleaning member 400 passes through the cleaning member 400 and is supplied to the gap between the cleaning member 400 and the surface to be cleaned 600.

Similarly, when the on-off valve 241B is opened, the liquid from the liquid supply source 243 is supplied through the liquid supply line 240B to the cleaning member 400. The liquid supplied to the cleaning member 400 passes through the cleaning member 400 and is supplied to the gap between the cleaning member 400 and the surface to be cleaned 600.

As shown in FIG. 7, the cleaning member 400 is coupled to an oscillation mechanism 700 as a moving mechanism and a lifting mechanism 800 as a distance adjustment mechanism. The oscillation mechanism 700 is configured to oscillate the cleaning member 400 in a direction parallel to the surface to be cleaned 600 by its operation. The lifting mechanism 800 is configured to approach or separate the cleaning member 400 from the surface to be cleaned 600 by its operation.

The oscillation mechanism 700 corresponds to at least one of the oscillation mechanism 86 (see FIG. 2), the arm oscillation mechanism 79 (see FIG. 5), and the arm oscillation mechanism 221 (see FIG. 6). The lift mechanism 800 corresponds to the distance adjustment mechanism described above (i.e., at least one of the lifting mechanism 87 shown in FIG. 2, the lifting mechanisms 64a and 64b shown in FIG. 3, the lifting mechanism 74 shown in FIG. 5, and the lifting mechanism 222 shown in FIG. 6).

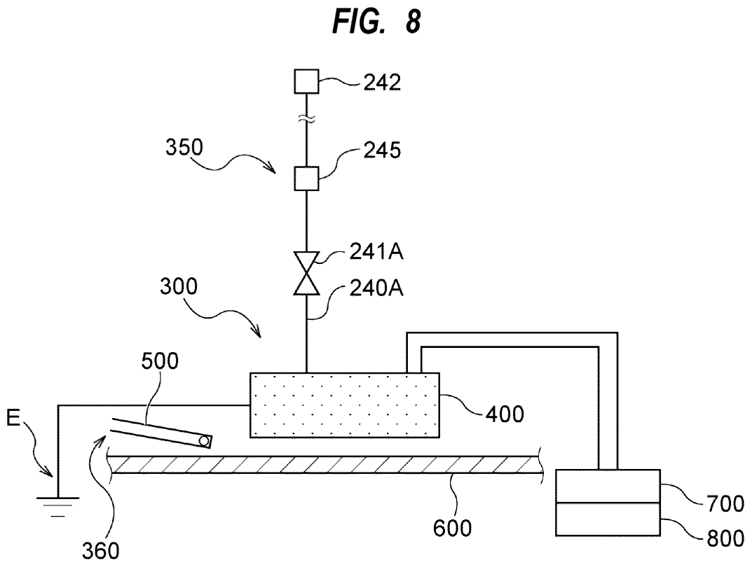

FIG. 8 is a view showing another embodiment of the fine bubble cleaning mechanism. As shown in FIG. 8, the liquid supply device 360 does not necessarily have to have the liquid supply line 240B and the on-off valve 241B (see FIG. 7), and may have a liquid supply nozzle 500.

The liquid supply nozzle 500 is configured to supply the liquid to a gap between the cleaning member 400 and the surface to be cleaned 600. The liquid supply nozzle 500 corresponds to at least one of the supply nozzles 82A, 82B, and 82C (see FIG. 2), the supply nozzles 65, 66, 67, and 68 (see FIG. 3), the supply nozzles 75, 76, 77, and 78 (see FIG. 5), and the supply nozzles 230A and 230B (see FIG. 6).

When the liquid supply device 360 supplies the liquid to the gap between the cleaning member 400 and the surface to be cleaned 600, the cleaning member 400 cleans the surface to be cleaned 600 in a presence of the liquid. With the liquid being supplied from the liquid supply device 360, the gas supply device 350 generates fine bubbles in the gap between the cleaning member 400 and the surface to be cleaned 600 through the cleaning member 400 having the open-cell foam structure.

More specifically, under a condition that the liquid is present in the gap between the cleaning member 400 and the surface to be cleaned 600, by opening the on-off valve 241A, the gas from the gas supply source 242 is supplied to the gap between the cleaning member 400 and the surface to be cleaned 600 through the gas supply line 240A and the cleaning member 400. As a result, fine bubbles are generated in the liquid in the gap between the cleaning member 400 and the surface to be cleaned 600.

As shown in FIGS. 7 and 8, the gas supply device 350 includes a pressure regulator 245 that regulates a pressure of the gas supplied to the cleaning member 400. The pressure regulator 245 is connected to the gas supply line 240A, and is electrically connected to the control device 30. The control device 30 is configured to be able to control an operation of the pressure regulator 245.

The control device 30 is configured to operate the pressure regulator 245 to regulate the amount of gas supplied to the gap between the cleaning member 400 and the surface to be cleaned 600, thereby retaining fine bubbles in the cleaning member 400.

The control device 30 is configured to operate the pressure regulator 245 to regulate the amount of gas supplied to the gap between the cleaning member 400 and the surface to be cleaned 600, thereby continuously supplying fine bubbles from the cleaning member 400.

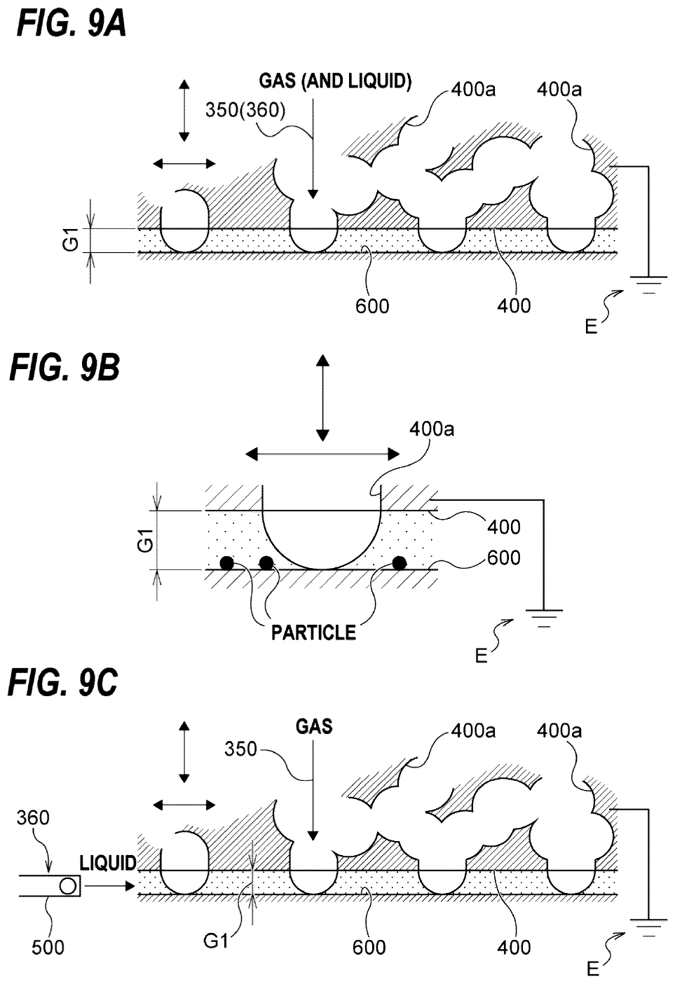

FIG. 9A is a view showing how fine bubbles are generated from the cleaning member, FIG. 9B is a view showing how the cleaning member removes particles, and FIG. 9C is a view showing how fine bubbles are generated from the cleaning member.

In the embodiment shown in FIG. 9A, the gas supply device 350 and the liquid supply device 360 supply the gas and the liquid to the cleaning member 400. With this configuration, the cleaning member 400 generates fine bubbles from its surface. In the embodiment shown in FIG. 9C, the gas supply device 350 supplies the gas to the cleaning member 400, and the liquid supply nozzle 500 as the liquid supply device 360 supplies the liquid to the gap between the cleaning member 400 and the surface to be cleaned 600. With this configuration, the cleaning member 400 generates fine bubbles from its surface.

As shown in FIGS. 9A to 9C, the cleaning member 400 having the open-cell foam structure has a large number of pores 400a formed therein. The pores 400a have a size of 100 nanometers or less (or less than 1 micrometer) and open on the surface of the cleaning member 400. The gas supply device 350 (more specifically, the gas supply line 240A) is arranged on a side opposite the surface of the cleaning member 400.

When the liquid supply device 360 supplies the liquid to the gap between the cleaning member 400 and the surface to be cleaned 600 while the gas supply device 350 generates fine bubbles through the pores 400a of the cleaning member 400, the gap between the cleaning member 400 and the surface to be cleaned 600 is filled with the liquid containing fine bubbles (see FIGS. 9A and 9C).

The fine bubbles include ultra-fine bubbles and microbubbles. The ultra-fine bubbles are fine bubbles having a bubble diameter of 1 micrometer or less. The microbubbles are fine bubbles having a bubble diameter of 1 micrometer to 100 micrometers or less.

The fine bubble cleaning mechanism 300 is configured to supply ultra-fine bubbles and/or microbubbles to the gap between the cleaning member 400 and the surface to be cleaned 600 depending on a size of the pores (in this embodiment, the pores 400a of the cleaning member 400) in the open-cell foam structure.

The lifting mechanism 800 as a distance adjustment mechanism is configured to move the cleaning member 400 to a bubble contact position where the fine bubbles are brought into contact with the surface to be cleaned 600, while the fine bubbles are held in the cleaning member 400 by the gas supply device 350. In the embodiment shown in FIGS. 9A to 9C, when the cleaning member 400 is moved to the bubble contact position, a distance G1 between the cleaning member 400 and the surface to be cleaned 600 is 1 micrometer or less.

According to this embodiment, the cleaning member 400 can remove particles (and/or slurry) by the fine bubbles held on its surface. In particular, the fine bubbles that come into contact with the particles have a size equivalent to that of the particles, so that the cleaning member 400 that holds the fine bubbles effectively removes the particles. As a result, the substrate processing module including the fine bubble cleaning mechanism 300 can improve the cleaning efficiency of the object to be cleaned.

Furthermore, when the oscillation mechanism 700 oscillates the cleaning member 400 in this state, the fine bubbles held by the cleaning member 400 move in a direction parallel to the surface to be cleaned 600 to come into sliding contact with a surface of the surface to be cleaned 600. In this manner, by moving the cleaning member 400, which holds the fine bubbles on its surface, to the bubble contact position and oscillating it, the cleaning member 400 can more effectively remove particles (and/or slurry) present on the surface to be cleaned 600.

Since the distance G1 between the cleaning member 400 and the surface to be cleaned 600 is very small, the cleaning member 400 is in partial contact with the surface to be cleaned 600. Therefore, the cleaning member 400 can exert a combined cleaning effect by cleaning with the fine bubbles held in the cleaning member 400 and cleaning by physical contact of the cleaning member 400.

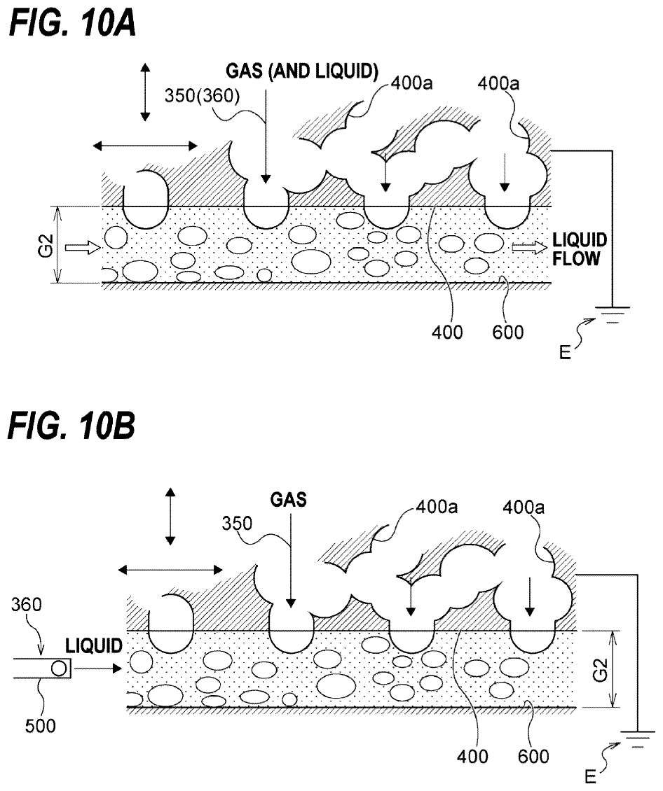

FIGS. 10A and 10B are views showing the cleaning member moved to a bubble separation position. In the embodiment shown in FIG. 10A, the gas and the liquid are supplied to the cleaning member 400, so that the cleaning member 400 generates fine bubbles from its surface. In the embodiment shown in FIG. 10B, the gas is supplied to the cleaning member 400, and the liquid is supplied from the liquid supply nozzle 500, so that the cleaning member 400 generates fine bubbles from its surface.

The lifting mechanism 800, which serves as a distance adjustment mechanism, is configured to move the cleaning member 400 to the bubble separation position where the fine bubbles are separated from the surface to be cleaned 600 further than the bubble contact position, while the fine bubbles are continuously supplied from the cleaning member 400 by the gas supply device 350.

In embodiments shown in FIGS. 10A and 10B, when the cleaning member 400 is moved to the bubble separation position, a distance G2 between the cleaning member 400 and the surface to be cleaned 600 is greater than 1 micrometer. In other words, the distance G2 is greater than the distance G1 (G2>G1).

According to this embodiment, by moving the cleaning member 400 to the bubble separation position while continuously supplying fine bubbles from the cleaning member 400, the gap between the cleaning member 400 and the surface to be cleaned 600 is filled with the liquid containing a large amount of fine bubbles (i.e., high-density bubble liquid). Therefore, the large amount of fine bubbles contained in the liquid can remove particles (and the slurry) present on the surface to be cleaned 600.

If necessary, the liquid supply device 360 may generate a flow (liquid flow) of the liquid supplied to the gap between the cleaning member 400 and the surface to be cleaned 600 in combination with the operation of the oscillation mechanism 700 (see FIGS. 10A and 10B).

Furthermore, according to the present embodiment, the fine bubbles have a radical effect of generating radicals having a bactericidal effect, and therefore, the substrate processing module can improve a cleaning performance of the object by cleaning the surface to be cleaned 600 with the fine bubbles.

As described above, the cleaning member 400 having the open-cell foam structure may be made of a resin material. In this case, when the liquid supplied from the liquid supply source 243 comes into contact with the cleaning member 400, the cleaning member 400 is likely to become charged with electricity. In particular, when the liquid has a high specific resistance, such as pure water, the cleaning member 400 is very likely to become charged with electricity.

If the cleaning member 400 is charged with electricity, an electric discharge occurs between the cleaning member 400 and the surface to be cleaned 600. In particular, when the object to be cleaned is the wafer W, the surface of the wafer W may be damaged by the electric discharge. Therefore, the cleaning member 400 having the open-cell foam structure is made of a conductive resin that is grounded by an earth E (see FIGS. 7 and 8). For example, the cleaning member 400 may be made of a resin containing carbon nanotubes (CNTs).

The cleaning member 400 made of the conductive resin can prevent charging with electricity by the earth E attached to the cleaning member 400. As a result, a damage to the surface of the wafer W caused by the electric discharge can be prevented.

In one embodiment, the control device 30 may be configured to supply an electric current to the cleaning member 400 through the earth E. With such a configuration, the control device 30 can control properties of the liquid containing fine bubbles to perform characteristic bubble cleaning.

For example, the control device 30 can forcibly impart the same electric charge to the fine bubbles contained in the liquid by supplying the electric current to the cleaning member 400. As a result, adjacent fine bubbles repel each other, preventing the micro-bubbles from combining with each other.

In particular, by arranging the cleaning member 400 at the bubble separation position and continuously supplying fine bubbles from the cleaning member 400, a large amount of fine bubbles are present in the gap between the cleaning member 400 and the surface to be cleaned 600 (see FIGS. 10A and 10B).

By applying the same electric charge to the micro-bubbles, it is possible to more effectively prevent a large number of fine bubbles from combining with each other to form large bubbles, which may adversely affect the cleaning effect of the wafer W. This configuration can improve the cleaning effect of the wafer W.

For example, when the surface of the wafer W is negatively charged with electricity and the particles are positively charged with electricity, the particles tend to adhere to the surface of the wafer W. Therefore, by supplying the electric current to the cleaning member 400 to negatively charge with electricity the fine bubbles, the particles actively adhere to the fine bubbles, while the fine bubbles to which the particles are attached repel the surface of the wafer W. Therefore, with this configuration, it is possible to more effectively prevent the particles from re-adhering to the surface of the wafer W.

In one embodiment, the substrate processing module may include an ultrasonic vibrator 260 (see FIG. 7) for applying ultrasonic waves to the liquid supplied from the liquid supply device 360. In the embodiment shown in FIG. 7, the ultrasonic vibrator 260 is connected to the liquid supply line 240B.

The ultrasonic vibrator 260 is configured to apply ultrasonic waves to the liquid supplied to the cleaning member 400 through the supply line 240B. With this configuration, the fine bubbles contained in the liquid supplied from the cleaning member 400 are ultrasonically vibrated by the ultrasonic vibrator 260. As a result, the ultrasonically vibrated fine bubbles can more effectively remove particles (and/or slurry) on the surface to be cleaned 600.

A frequency of the ultrasonic vibration applied to the liquid containing the fine bubbles is desirably a frequency that resonates with the fine bubbles contained in the liquid. A height of the frequency depends on the size of the fine bubbles. Therefore, a larger the size of the fine bubbles, the higher the frequency of the ultrasonic vibration applied.

By moving the cleaning member 400 to the bubble separation position while the fine bubbles are being continuously supplied from the cleaning member 400, it is possible to fill the gap between the cleaning member 400 and the surface to be cleaned 600 with the liquid containing a large amount of fine bubbles. In this state, when the ultrasonic vibrator 260 ultrasonically vibrates a large amount of fine bubbles, the cleaning effect of the object to be cleaned can be further improved.

Although not shown, the ultrasonic vibrator 260 may be coupled to the liquid supply nozzle 500. Even with such a configuration, the ultrasonic vibrator 260 can ultrasonically vibrate the fine bubbles contained in the liquid supplied to the gap between the cleaning member 400 and the surface to be cleaned 600 by applying ultrasonic waves to the liquid supplied from the liquid supply nozzle 500. As a result, the same effect as that described above can be achieved.

In one embodiment, the substrate processing module may include a temperature regulator 270 (see FIG. 7) for regulating the temperature of the liquid supplied from the liquid supply device 360. In the embodiment shown in FIG. 7, the temperature regulator 270 is connected to the liquid supply line 240B.

The temperature regulator 270 is configured to regulate the temperature of the liquid supplied to the cleaning member 400 through the supply line 240B. When the temperature regulator 270 increases the temperature of the liquid passing through the supply line 240B, the fine bubbles contained in the liquid are activated by Brownian motion caused by a thermal motion of the liquid, and the particles (and/or slurry) on the surface to be cleaned 600 can be removed more effectively.

Although not shown, the temperature regulator 270 may be coupled to the liquid supply nozzle 500. Even with such a configuration, the temperature regulator 270 can regulate the temperature of the liquid supplied from the liquid supply nozzle 500, thereby activating the fine bubbles contained in the liquid supplied to the gap between the cleaning member 400 and the surface to be cleaned 600. As a result, the same effect as that described above can be achieved.

As described above, the fine bubble cleaning mechanism 300 can also be applied to the substrate processing module described with reference to FIGS. 2 to 6. In the embodiment shown in FIG. 2, the fine bubble cleaning mechanism 300 includes the gas supply device 350 and the liquid supply device 360 connected to the cleaning member 85a. In the embodiment shown in FIG. 3 (and FIG. 4), the fine bubble cleaning mechanism 300 includes the gas supply device 350 and the liquid supply device 360 connected to the cleaning members 61 and 62.

In the embodiment shown in FIG. 5, the fine bubble cleaning mechanism 300 includes the gas supply device 350 and the liquid supply device 360 connected to the cleaning member 71. In the embodiment shown in FIG. 6, the fine bubble cleaning mechanism 300 includes the gas supply device 350 and the liquid supply device 360 connected to the cleaning member 211.

In FIGS. 2 to 6, the gas supply source 242 and the pressure regulator 245 (see FIG. 7), and the liquid supply source 243 (see FIG. 7) are omitted. Although not shown, the ultrasonic vibrator 260 and the temperature regulator 270 may also be applied to the embodiment described with reference to FIGS. 2 to 6 (see FIG. 7).

In the above-described embodiment, the substrate cleaning module is configured to clean the wafer W while holding the wafer W horizontally. However, the substrate cleaning module does not necessarily need to hold the wafer W horizontally. Hereinafter, the substrate cleaning module that holds the wafer W vertically will be described with reference to the drawings.

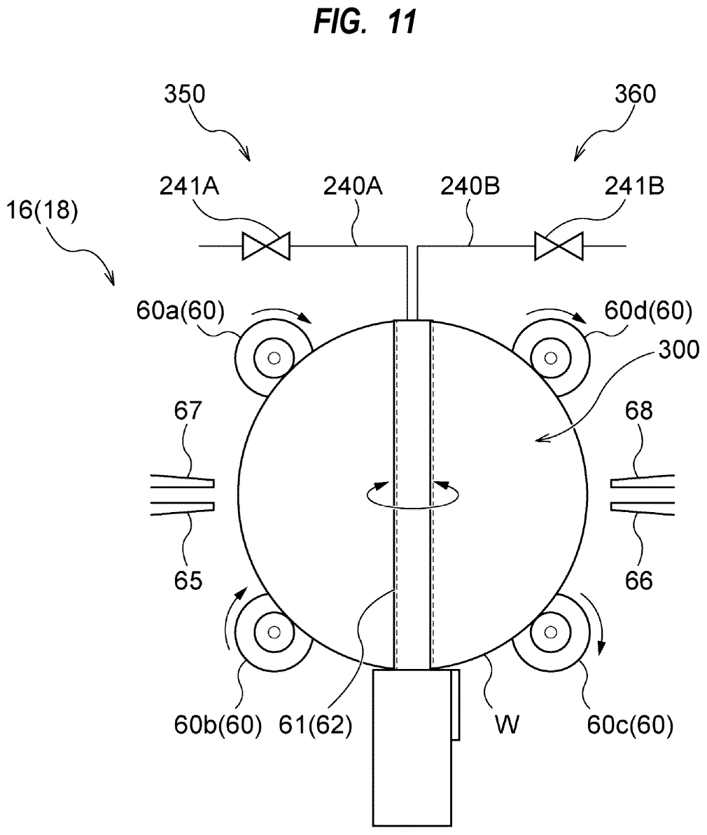

FIGS. 11 to 13 are views showing the substrate cleaning module that holds the wafer vertically. In the embodiment shown in FIG. 11, the substrate holding mechanism 60 is configured to hold the wafer W vertically (i.e., plumb), and the fine bubble cleaning mechanism 300 is configured to clean the wafer W held vertically.

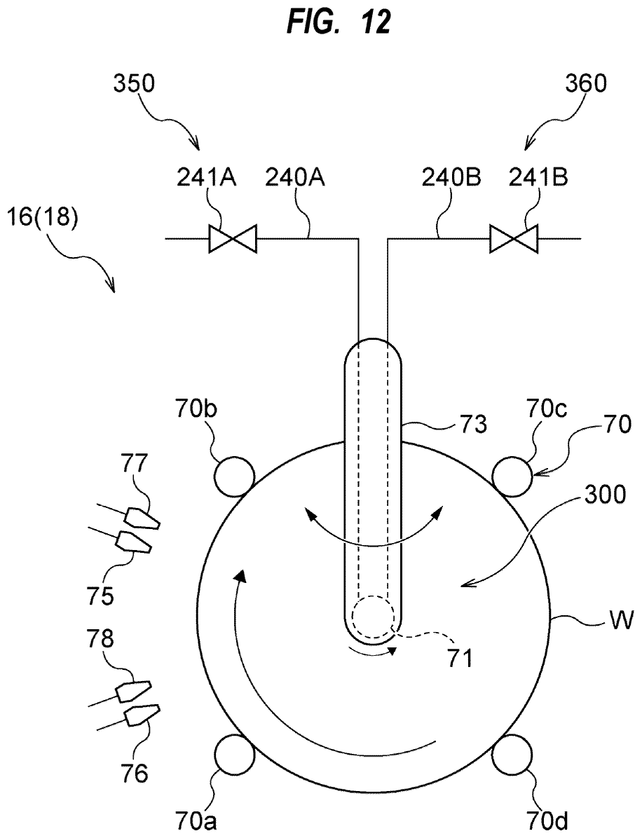

In the embodiment shown in FIG. 12, the substrate holding mechanism 70 is configured to hold the wafer W vertically, and the fine bubble cleaning mechanism 300 is configured to clean the wafer W held vertically.

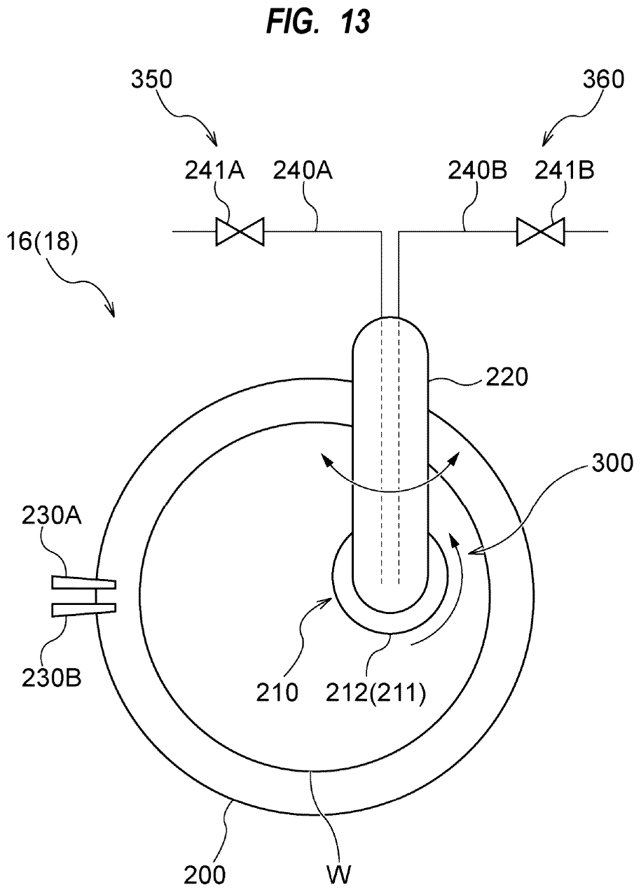

In the embodiment shown in FIG. 13, the rotary table 200 is configured to hold the wafer W vertically, and the fine bubble cleaning mechanism 300 is configured to clean the wafer W held vertically.

In this manner, the fine bubble cleaning mechanism 300 may be configured to clean the vertically held wafer W. Even with such a configuration, the fine bubble cleaning mechanism 300 can achieve the same effects as those of the embodiment described with reference to FIGS. 2 to 10.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A substrate processing module for processing a substrate, comprising:
a cleaning member having an open-cell foam structure;
a gas supply device configured to supply a gas to a gap between the cleaning member and a surface to be cleaned of an object to be cleaned; and
a liquid supply device configured to supply a liquid to the gap between the cleaning member and the surface to be cleaned,
wherein the gas supply device is configured to generate a fine bubble through the open-cell foam structure while supplying the liquid from the liquid supply device.

2. The substrate processing module according to claim 1,
wherein the substrate processing module comprises a distance adjustment mechanism configured to approach or separate the cleaning member from the surface to be cleaned, and
wherein the distance adjustment mechanism is configured to move the cleaning member to a bubble contact position where the fine bubble comes into contact with the surface to be cleaned in a state where the fine bubble is held in the open-cell foam structure by the gas supply device.

3. The substrate processing module according to claim 2,
wherein the distance adjustment mechanism is configured to move the cleaning member to a bubble separation position where the fine bubble is separated from the surface to be cleaned further than the bubble contact position, while continuously supplying the fine bubble from the open-cell foam structure by the gas supply device.

4. The substrate processing module according to claim 1,
wherein the substrate processing module includes an ultrasonic vibrator configured to apply ultrasonic waves to the liquid supplied from the liquid supply device.

5. The substrate processing module according to claim 1,
wherein the substrate processing module comprises a temperature regulator configured to regulate a temperature of the liquid supplied from the liquid supply device.

6. The substrate processing module according to claim 1,
wherein the open-cell foam structure is made of a grounded conductive resin.

7. The substrate processing module according to claim 6,
wherein the open-cell foam structure of the conductive resin has fine pores.

8. The substrate processing module according to claim 1,
wherein the substrate processing module comprises a moving mechanism configured to move the cleaning member parallel to the surface to be cleaned, and
wherein the moving mechanism is configured to move the cleaning member in a radial direction of the surface to be cleaned while the fine bubble is in contact with the surface to be cleaned.

9. A substrate processing method for processing a substrate, comprising:
supplying a liquid to a gap between a cleaning member having an open-cell foam structure and a surface to be cleaned of an object to be cleaned; and
supplying a fine bubble to the gap between the cleaning member and the surface to be cleaned through the open-cell foam structure while supplying the liquid.

10. The substrate processing method according to claim 9, comprising: moving the cleaning member to a bubble contact position where the fine bubble comes into contact with the surface to be cleaned in a state where the fine bubble is held in the open-cell foam structure.

11. The substrate processing method according to claim 10, comprising: moving the cleaning member to a bubble separation position where the fine bubble is separated from the surface to be cleaned further than the bubble contact position while continuously supplying the fine bubble from the open-cell foam structure.

12. The substrate processing method according to claim 9, comprising: applying ultrasonic waves to the liquid when the fine bubble is supplied to the gap between the cleaning member and the surface to be cleaned.

13. The substrate processing method according to claim 9, comprising: regulating a temperature of the liquid when the fine bubble is supplied to the gap between the cleaning member and the surface to be cleaned.

14. The substrate processing method according to claim 9, wherein the open-cell foam structure is made of a grounded conductive resin.

15. The substrate processing method according to claim 14, wherein the open-cell foam structure of the conductive resin has fine pores.

16. The substrate processing method according to claim 9, comprising: moving the cleaning member in a radial direction of the surface to be cleaned while the fine bubble is in contact with the surface to be cleaned.
